(19) United States
(12) Patent Application Publication
(10) Pub. No.: US 2012/0273824 A1
(43) Pub. Date: Nov. 1, 2012

(54) OPTOELECTRONIC SEMICONDUCTOR CHIP

(75) Inventors: Nikolaus Gmeinwieser, Obertraubling (DE); Matthias Sabathil, Regensburg (DE); Andreas Leber, Regensburg (DE)

(73) Assignee: OSRAM Opto Semiconductors GmbH, Regensburg (DE)

(21) Appl. No.: 13/517,110

(22) PCT Filed: Dec. 15, 2010
(86) PCT No.: PCT/EP2010/069776

§ 371 Date: Jul. 17, 2012

(30) Foreign Application Priority Data
Dec. 21, 2009 (DE) 10 2009 059 887.1

(51) Int. Cl. H01L 33/58

(52) U.S. Cl. 257/98; 257/E33.073

(57) ABSTRACT

An optoelectronic semiconductor chip includes a semiconductor layer sequence having an active layer and a light-outcoupling layer applied at least indirectly on a radiation permeable surface of the semiconductor layer sequence. A material of the light-outcoupling layer is different from a material of the semiconductor layer sequence and refractive indices of the materials of the light-outcoupling layer and of the semiconductor layer sequence differ from each other by 20% at most. Recesses in the light-outcoupling layer form facets, wherein the recesses do not penetrate the light-outcoupling layer completely. The facets have a total area of at least 25% of an area of the radiation permeable surface.

### RELATED APPLICATIONS

This is a §371 of International Application No. PCT/EP2010/069776, with an international filing date of Dec. 15, 2010 (WO 2011/085895, published Jul. 21, 2011), which claims the priority of German Patent Application No. 10 2009 059 887.1, filed Dec. 21, 2009, the entire contents of which are hereby incorporated by reference.

### TECHNICAL FIELD

This disclosure relates to an optoelectronic semiconductor chip.

### BACKGROUND

US 2007/0267640 A1 describes a light-emitting semiconductor diode and a method of production therefor. It could be helpful, however, to provide an optoelectronic semiconductor chip which can be produced efficiently and has a high level of light-outcoupling efficiency.

### SUMMARY

We provide an optoelectronic semiconductor chip including a semiconductor layer sequence having at least one active layer that generates electromagnetic radiation, and a light-outcoupling layer applied at least indirectly on a radiation permeable surface of the semiconductor layer sequence, wherein a material of the light-outcoupling layer is different from a material of the semiconductor layer sequence, refractive indices of the materials of the light-outcoupling layer and the semiconductor layer sequence differ from each other by 20% at most, recesses in the light-outcoupling layer form outcoupling structures with facets, the light-outcoupling layer is not completely penetrated by the recesses in regions on the radiation permeable surface, and the facets of the recesses have a total area which is at least 25% of an area of the radiation permeable surface.

We also provide an optoelectronic semiconductor chip including a semiconductor layer sequence having at least one active layer that generates electromagnetic radiation, and a light-outcoupling layer applied at least indirectly on a radiation permeable surface of the semiconductor layer sequence, wherein a material of the light-outcoupling layer is different from a material of the semiconductor layer sequence, refractive indices of the materials of the light-outcoupling layer and the semiconductor layer sequence differ from each other by 20% at most, recesses in the light-outcoupling layer form outcoupling structures with facets, the light-outcoupling layer is not completely penetrated by the recesses in regions on the radiation permeable surface, the facets of the recesses have a total area which is at least 25% of an area of the radiation permeable surface, an electrically conductive layer is applied on a side of the light-outcoupling layer remote from the semiconductor layer sequence, wherein the conductive layer is penetrated completely by the recesses and does not cover the facets, and the light-outcoupling layer is electrically conductive and has an average surface resistance of 2.5Ω/□ to 50Ω/□.

### BRIEF DESCRIPTION OF THE DRAWINGS

FIGS. 1 to 6 show schematic illustrations of examples of optoelectronic semiconductor chips.

FIG. 7 shows schematic illustrations of further semiconductor chips.

### DETAILED DESCRIPTION

The optoelectronic semiconductor chip may include a semiconductor layer sequence having one or several active layers. The at least one active layer is arranged to generate electromagnetic radiation, in particular, in the ultraviolet or blue spectral range. The at least one active layer can comprise at least one pn-transition and/or one or several quantum wells of any dimensionality. For example, the semiconductor chip is formed as a thin film chip, as described in WO 2005/081319 A1, the subject matter with regard to the semiconductor chip described therein and the production method described therein is incorporated herein by reference. Moreover, the semiconductor layer sequence can comprise additional layers such as outer layers and/or current spreading layers. For example, the semiconductor layer sequence is formed as a light-emitting diode or as a laser diode.

The entire semiconductor layer sequence may be based upon the same material system. In this case, individual layers of the semiconductor layer sequence can comprise a mutually different composition of functional material components, in particular, different dopings. Preferably, the semiconductor layer sequence is based upon GaN, GaP or GaAs, wherein in specific terms a proportion of e.g. Al and/or In can vary within the semiconductor layer sequence. The semiconductor layer sequence can also include varying proportions of P, B, Mg and/or Zn.

The semiconductor chip may comprise a light-outcoupling layer applied indirectly or directly on a radiation permeable surface of the semiconductor layer sequence. Preferably, the light-outcoupling layer is in direct contact with a material of the semiconductor layer sequence and/or applied onto the semiconductor layer sequence in a form-fitting manner with respect to the radiation permeable surface.

In specific terms, the radiation permeable surface of the optoelectronic semiconductor chip is the surface—which is in particular planar within the scope of production tolerances—which is oriented perpendicularly with respect to a growth direction of the semiconductor layer sequence and which delimits the semiconductor layer sequence in a direction perpendicular to the growth direction. In other words, the radiation permeable surface is one of the main sides of the semiconductor layer sequence, in particular that one of the main sides of the semiconductor layer sequence remote from a carrier or a substrate, on which the semiconductor layer sequence is applied or grown. The radiation permeable surface is arranged such that at least some of the radiation generated in the semiconductor layer sequence leaves the semiconductor layer sequence through the radiation permeable surface. Regions, through which no radiation can leave the semiconductor layer sequence, e.g. regions of the semiconductor layer sequence coated with metallic webs for the purpose of current spreading, specifically do not form part of the radiation permeable surface.

A material of the light-outcoupling layer may be different from a material of the semiconductor layer sequence. In other words, the semiconductor layer sequence and the light-outcoupling layer are based upon different materials and/or material systems. In particular, the light-outcoupling layer is free of a material or a material component of the semiconductor layer sequence.

A refractive index or an average refractive index of the material of the light-outcoupling layer may differ from a refractive index or an average refractive index of the semiconductor layer sequence by 20% at most. In other words, the value of the quotient from the difference in the refractive indices of the materials of the light-outcoupling layer and the semiconductor layer sequence and the refractive index of the material of the semiconductor layer sequence is less than or equal to 0.2. In this case, the material of the semiconductor layer sequence is to be understood to be in particular the material of the semiconductor layer sequence, by which the radiation permeable surface is formed. Preferably, the refractive indices of the semiconductor layer sequence and the light-outcoupling layer differ from each other by 10% at most, in particular by 5% at most. Particularly preferably, the refractive indices are equal or equal as far as possible. In this case, the term refractive index refers to a refractive index at a wavelength generated in the active layer during operation of the semiconductor chip, in particular at a main wavelength, i.e., a wavelength, at which an intensity of the generated radiation per nm spectral width is at a maximum.

Outcoupling structures may be formed by recesses in the light-outcoupling layer, wherein the recesses comprise facets. In this case, the recesses do not penetrate the light-outcoupling layer completely. In other words, no material of the semiconductor layer sequence is exposed by the recesses. In particular, the at least one active layer of the semiconductor layer sequence is not penetrated by the recesses.

Preferably, facets are all such boundary surfaces of the recesses which form an angle with the radiation permeable surface which is 15° to 75°, in particular 30° to 60°. The facets can be formed by individual or contiguous surfaces of the recesses which delimit the recesses in the lateral direction.

The facets may comprise a total area which is at least 25% of an area of the radiation permeable surface. Preferably, the total area of all facets, in particular those facets located in a direction perpendicular to the radiation permeable surface above the active layer, constitutes at least 75% or at least 100% of the area of the radiation permeable surface. Since the facets are aligned transversely with respect to the radiation permeable surface, the total area of the facets can even be greater than the area of the radiation permeable surface.

The optoelectronic semiconductor chip may include a semiconductor layer sequence having at least one active layer that generates electromagnetic radiation. Furthermore, the semiconductor chip comprises a light-outcoupling layer applied at least indirectly on a radiation permeable surface of the semiconductor layer sequence. A material of the light-outcoupling layer is different from a material of the semiconductor layer sequence and refractive indices of the materials of the light-outcoupling layer and of the semiconductor layer sequence differ from each other by 20% at most. Recesses in the light-outcoupling layer serve to form outcoupling structures with facets, wherein the light-outcoupling layer is not completely penetrated at least by those recesses located in a direction perpendicular to the radiation permeable surface above the active layer. Moreover, the facets of the recesses have a total area which corresponds to at least 25% of an area of the radiation permeable surface of the semiconductor layer sequence.

By virtue of the fact that a light-outcoupling layer is applied on the semiconductor layer sequence, in which outcoupling structures are produced, it is possible to prevent outcoupling structures from being produced in the semiconductor layer sequence itself. As a consequence, the thickness of the semiconductor layer sequence can be reduced, whereby stresses in the semiconductor layer sequence can likewise be reduced and whereby production costs for the semiconductor chip can be lowered. A high level of outcoupling efficiency can be achieved specifically by virtue of the fact that a refractive index of the light-outcoupling layer corresponds substantially to the refractive index of the semiconductor layer sequence.

A part of the light-outcoupling layer may be located in a lateral direction next to the semiconductor layer sequence. In other words, in a direction perpendicular to the radiation permeable surface, this part of the light-outcoupling layer does not extend over the active layer and/or over the semiconductor layer sequence.

Some of the recesses in the lateral part of the light-outcoupling layer provided next to the semiconductor layer sequence, preferably all of the recesses in this part of the light-outcoupling layer, may extend through a plane in which the active layer or one of the active layers is located. In other words, the plane is defined by the active layer. The plane extends through the active layer or, in the case of several active layers, preferably through the active layer which is the furthest removed from the radiation permeable surface. Furthermore, the plane is oriented in particular perpendicularly with respect to a growth direction of the semiconductor layer sequence, i.e. for example in parallel with the radiation permeable surface. In other words, radiation exiting the active layer in parallel with the radiation permeable surface impinges upon at least some of the recesses in the part of the light-outcoupling layer provided laterally next to the semiconductor layer sequence.

The recesses may comprise a spherical basic shape, a pyramidal basic shape, a truncated pyramidal basic shape, a truncated conical basic shape and/or a conical basic shape. Preferably, a diameter of the recesses increases in a direction away from the radiation permeable surface.

The recesses may comprise boundary surfaces which within the scope of production tolerances can be described by a function which can be once continuously differentiable, wherein the boundary surfaces form the facets or some of the facets. Preferably, the first derivation of this function is in local terms in each case a constant in at least one spatial direction. In other words, the recesses are then formed e.g. in the manner of a truncated cone and the facets are formed by an outer surface of the truncated cone.

The recesses may be disposed in a regular two-dimensional grid above the radiation permeable surface, wherein an average grid constant of the grid is at least double, in particular at least triple the main wavelength of the radiation produced in the active layer. In this case, the main wavelength is related to a medium into which the radiation enters. If the semiconductor chip is surrounded e.g. by air, then a refractive index of the medium is approximately 1 and the main wavelength corresponds to a vacuum main wavelength. If the semiconductor chip is surrounded by a casting compound, e.g. a silicone, then the main wavelength is the vacuum wavelength divided by the refractive index of the casting compound.

The recesses may comprise inner boundary surfaces, wherein the inner boundary surfaces adjoin the facets in a direction towards the semiconductor layer sequence. A total area of the inner boundary surfaces corresponds to at least 5% or at least 10%, preferably at least 15% or at least 20% of the area of the radiation permeable surface.

The recesses and/or the light-outcoupling layer may comprise outer boundary surfaces. The outer boundary surfaces are those surfaces of the light-outcoupling layer and/or of the recesses located further away from the semiconductor layer sequence than the surfaces of the recesses which form the facets and/or which delimit the facets in a direction away from the semiconductor layer sequence or adjoin the facets in this direction. Furthermore, a total area of the outer boundary surfaces is at least 10%, in particular at least 20% or at least 30% of the area of the radiation permeable surface.

An electrically conductive layer may be applied on the light-outcoupling layer on a side remote from the semiconductor layer sequence. The conductive layer is completely penetrated by the recesses in the light-outcoupling layer, wherein the facets are then not covered by the conductive layer or the conductive layer is formed preferably in a form-fitting manner in relation to the recesses and covers the facets partially or completely. The average thickness of the conductive layer is preferably less than an average thickness of the light-outcoupling layer and in particular is 500 nm at most or 300 nm at most and preferably at least 50 nm or at least 75 nm. Particularly preferably, the average thickness of the light-outcoupling layer is 250 nm, e.g. with a tolerance of 25 nm at most.

The conductive layer may be formed from a transparent conductive oxide, or TCO for short. Materials for the conductive layer are e.g. metal oxides like a zinc oxide, a tin oxide, a cadmium oxide, a titanium oxide, an indium oxide or an indium tin oxide (ITO), Zn₂SnO₄, CdSnO₃, ZnSnO₃, MgIn₂O₄, GaInO₃, Zn₂In₂O₅ or In₄Sn₃O₁₂ or mixtures thereof. Furthermore, the conductive layer can be p-doped or n-doped. Alternatively, the conductive layer can be formed from a transparent metal film which preferably has an average thickness of 20 nm at most or 10 nm at most. Combinations of such a metal film and a TCO can also be used, wherein the metal film is then preferably located on a side of the TCO remote from the light-outcoupling layer.

The light-outcoupling layer may be electrically conductive. For example, an average surface resistance of the light-outcoupling layer is 2.5Ω/□ to 50Ω/□ or 5Ω/□ to 25Ω/□. Alternatively or in addition, the specific resistance of a material of the light-outcoupling layer is 1×10⁴Ωcm to 5×10⁻³Ωcm or 2×10⁻⁴Ωcm to 2×10⁻³Ωcm.

The material of the light-outcoupling layer may be doped. A dopant is e.g. Mn, Nb or W, in particular if the material of the light-outcoupling layer is titanium oxide. A dopant concentration is preferably selected to be as small as possible, e.g. less than 5×10¹⁸ cm⁻³. This is made possible in particular by the electrically conductive layer on the light-outcoupling layer. In other words, lateral current spreading is then effected substantially only by the conductive layer and not by the light-outcoupling layer.

Our optoelectronic semiconductor chip will be explained in greater detail hereinafter with reference to the drawings and with the aid of examples. Like reference numerals designate like elements in the drawings. However, none of the references are illustrated to scale, on the contrary for better understanding individual elements can be illustrated to be excessively large.

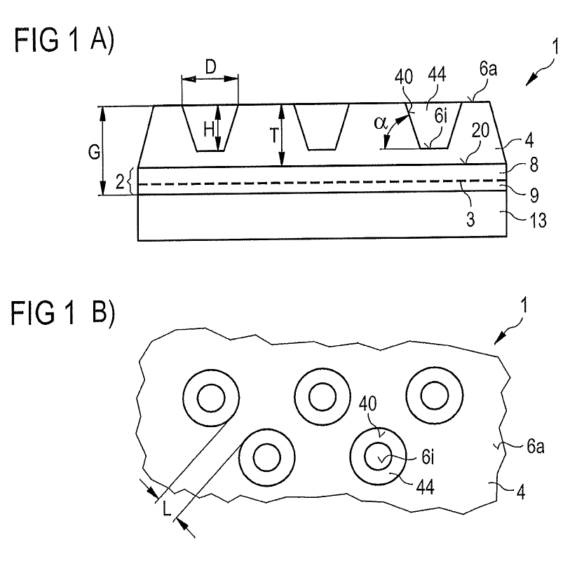

FIG. 1B illustrates a schematic plan view of a light-outcoupling layer 4 of an example of an optoelectronic semiconductor chip 1. FIG. 1A illustrates a sectional view of the semiconductor chip 1 along the dot-dash line in FIG. 1B.

A semiconductor layer sequence 2 having one or several active layers 3 is applied, e.g. grown or bonded, on a carrier 13. In the drawings, the active layer 3 is symbolized by a dashed line. It is possible that in the case of several active layers 3 they emit, during operation, radiation in at least two mutually different spectral ranges, e.g. with main wavelengths which are at least 15 nm or at least 20 nm apart from each other. The light-outcoupling layer 4 is applied on a radiation permeable surface 20 which is remote from the carrier 13 of the semiconductor layer sequence 2. The light-outcoupling layer 4 is in direct, immediate contact with a material of the semiconductor layer sequence 2 and formed in a form-fitting manner with respect to the radiation permeable surface 20. Furthermore, the light-outcoupling layer 4 is a contiguous, closed and continuous layer which covers the radiation permeable surface 20 completely or substantially, e.g. up to at least 80%.

Formed in the light-outcoupling layer 4 is a plurality of recesses 44. The recesses 44 comprise a truncated conical basic shape. Moreover, the recesses 44 are disposed in a regular grid having a hexagonal basic structure.

Lateral boundary surfaces of the recesses 44 form facets 40. The facets 40 have an angle a with respect to the radiation permeable surface 20 of 30° to 60°. The facets 40 have a total area which is at least 25% of the area of the radiation permeable surface 20.

In a direction towards the semiconductor layer sequence 2, the facets 40 adjoin inner boundary surfaces 6i of the recesses 44. The inner boundary surfaces 6i are oriented substantially in parallel with the radiation permeable surface 20 and have a total area which is at least 5% of the area of the radiation permeable surface 20. A contiguous outer boundary surface 6a is formed by a main side of the light-outcoupling layer 4 remote from the semiconductor layer sequence 2. The outer boundary surface 6a has an area which corresponds to at least 20% of the radiation permeable surface 20.

The thickness T of the light-outcoupling layer 4 is preferably 300 nm to 10 μm, in particular 1.0 μm to 5 μm or 2 μm to 4 μm. The depth H of the recesses 44 is 0.3 μm to 9.5 μm, in particular 0.5 μm to 3 μm. The average distance L between two adjacent recesses 44, as calculated from the edges on rims of the adjacent recesses 44, is 0.3 μm to 10 μm, preferably 1 μm to 5 μm.

The difference from the thickness T of the light-outcoupling layer 4 and depth H of the recesses 44 is e.g. an integer multiple of one quarter of the main wavelength of the radiation produced in the active layer 3, divided by the average refractive index of a material of the light-outcoupling layer 4. As a consequence, an anti-reflective effect of the light-outcoupling layer 4 can be achieved on the inner boundary surfaces 6i. The total thickness G of the semiconductor layer sequence 2 and the light-outcoupling layer 4 is preferably 4 μm to 12 μm.

The recesses 44 in the light-outcoupling layer 4 are produced e.g. by a photolithographic method, i.e. by application and structuring of a photoresist and subsequent etching, in particular by a dry-chemical etching process. After etching, the photoresist is preferably removed from the light-outcoupling layer 4.

It is likewise possible that as an alternative or in addition to the photoresist, a mask such as a hard mask, e.g. made of or with chromium, silicon dioxide and/or nickel is used. The photoresist can be removed from the hard mask prior to or after etching. After etching, the hard mask can remain on the light-outcoupling layer 4, not shown in FIG. 1, or can be removed like the photoresist.

These types of methods can be used to produce in particular a regular arrangement of recesses 44 in the light-outcoupling layer 4. Irregular roughening or irregular distribution of the recesses 44 can also be achieved such as by sand-blasting or etching the main side of the light-outcoupling layer 4 remote from the semiconductor layer sequence 2. Furthermore, it is possible that the recesses 44 are produced by a suitable method of applying the light-outcoupling layer 4 such as by a dripping process or by a spin-coating procedure in which a relief-like structure is formed.

As well as producing recesses 44 in the light-outcoupling layer 4 it is also possible to produce lateral boundary surfaces or facets of the semiconductor layer sequence 2, e.g. by an etching procedure.

A refractive index or an average refractive index of the light-outcoupling layer 4 is preferably 2.25 to 2.60, in particular 2.40 to 2.55. If the semiconductor layer sequence 2 is based e.g. upon GaN having a refractive index of ca. 2.5, the refractive indices of the semiconductor layer sequence 2 and the light-outcoupling layer 4 are then substantially equal. It is then possible to virtually avoid or at least considerably reduce any reflection of radiation at the boundary surface between the light-outcoupling layer 4 and the semiconductor layer sequence 2, thus increasing light-outcoupling efficiency of radiation from the semiconductor layer sequence 2. If the semiconductor layer sequence 2 is based e.g. upon InGaAlP having an refractive index of ca. 3, the light-outcoupling layer 4 then has a refractive index in particular of 2.7 to 3.3.

A material of the light-outcoupling layer 4 is then e.g. a titanium oxide such as titanium dioxide, a zinc sulphide, an aluminium nitride, a silicon carbide, a boron nitride and/or tantalum oxide. In the case of an electrically conductive light-outcoupling layer 4 which can be used e.g. for current spreading, the light-outcoupling layer 4 can include or consist of a transparent conductive oxide such as a particularly doped indium tin oxide. An average surface resistance of the light-outcoupling layer 4 is then preferably 2.5Ω/□ to 50Ω/□.

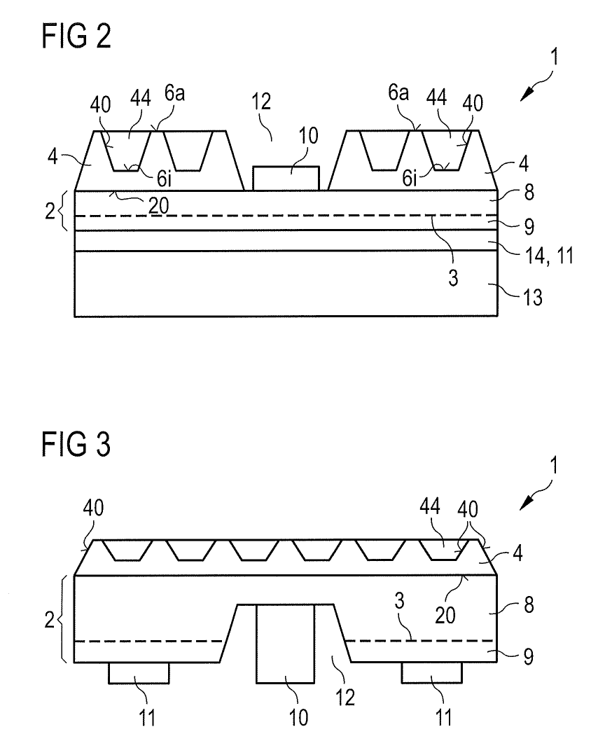

FIG. 2 illustrates a sectional view of a further example of the semiconductor chip 1. The semiconductor layer sequence 2 having an n-conductive layer 8 and a p-conductive layer 9 is attached to the carrier 13 via a connecting means 14, e.g. an electrically conductive metallic solder. The thickness of the p-conductive layer 9 is smaller than the thickness of the n-conductive layer 8. Located between the connector 14 and the semiconductor layer sequence 2 can be further layers, not shown, e.g. barrier layers, diffusion stop layers or reflective layers.

The connector layer 14 simultaneously produces a p-contact 11 via which the semiconductor layer sequence 2 can be supplied with current. Moreover, on the radiation permeable surface 20, an e.g. metallic n-contact 10 is applied directly onto the semiconductor layer sequence 2 in an opening 12 in the light-outcoupling layer 4. The light-outcoupling layer 4 thus surrounds the n-contact 10 in an annular manner. In this case, the light-outcoupling layer 4 is also a continuous, contiguous layer which covers more than 80% or more than 90% of the radiation permeable surface 20. The radiation permeable surface 20 is thus completely or almost completely covered by the n-contact 10 and the light-outcoupling layer 4.

In the example in accordance with the schematic sectional view in FIG. 3, the semiconductor layer sequence 2 comprises an opening 12 which penetrates the active layer 3 and extends as far as into the n-conductive layer 8. Formed in this opening 12 is the n-contact 10. The p-contacts 11 are located on a main side of the semiconductor layer sequence 2 remote from the radiation permeable surface 20. Within the scope of production tolerances, the semiconductor layer sequence 2 exhibits in a lateral direction the same extension as the light-outcoupling layer 4.

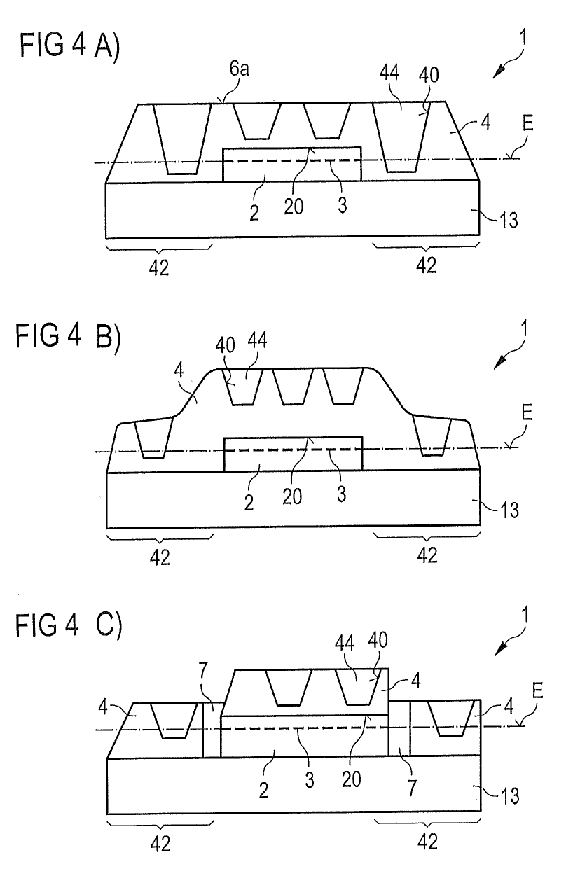

FIG. 4 illustrates further sectional illustrations of examples of the semiconductor chip 1. In accordance with FIG. 4A, the carrier 13 and the light-outcoupling layer 4 protrude beyond the semiconductor layer sequence 2 in a lateral direction, in parallel with the radiation permeable surface 20. Within the scope of production tolerances, the entire outer boundary surface 6a extends in a plane in parallel with the radiation permeable surface 20. In a part 42 of the light-outcoupling layer 4 located laterally next to the semiconductor layer sequence 2, the recesses 44 have a greater depth than in a region in a vertical direction above the semiconductor layer sequence 2. The recesses 44 in this part 42 of the light-outcoupling layer 4 penetrate a plane E defined by the active layer 3 and which extends substantially in parallel with the radiation permeable surface 20.

Unlike the illustration in FIG. 4A, the recesses 44 in the portion 42 next to the semiconductor layer sequence 2 can also completely penetrate the light-outcoupling layer 4 just like in the other examples. If the light-outcoupling layer 4 is formed with an electrically conductive material, then electrically insulating layers not shown in FIG. 4A can optionally be applied in particular on lateral boundary surfaces of the semiconductor layer sequence 2 and/or on the carrier 13, just like in all other examples.

In accordance with the examples in FIG. 4B, the light-outcoupling layer 4 has an approximately constant thickness over the entire lateral direction. Also, the depth of the recesses 44 is approximately constant over the entire lateral extension of the light-outcoupling layer 4. The recesses 44 intersect the plane E in the part 42 of the light-outcoupling layer 4. The light-outcoupling layer 4 can completely or partially cover partial regions of the carrier 13 not covered by the semiconductor layer sequence 2.

In the case of the example in accordance with FIG. 4C, the thickness of the light-outcoupling layer 4 is constant in a lateral direction. A trench 7 which completely surrounds the semiconductor layer sequence 2 is optionally formed between the part 42 of the light-outcoupling layer 4 next to the semiconductor layer sequence 2 and the light-outcoupling layer 4 in a vertical direction above the semiconductor layer sequence 2. The trench 7 completely penetrates the light-outcoupling layer 4 as far as to the carrier 13.

The part 42 of the light-outcoupling structure 4 disposed in a lateral direction next to the semiconductor layer sequence 2 has e.g. a width which is at least 5 μm, in particular 5 μm to 50 μm. Alternatively or in addition, the width is at least 5% or at least 10% of a width of the semiconductor layer sequence 2.

Unlike the illustration in FIG. 4C, it is also possible that the trench 7 which directly adjoins the semiconductor layer sequence 2 does not completely penetrate the light-outcoupling layer 4.

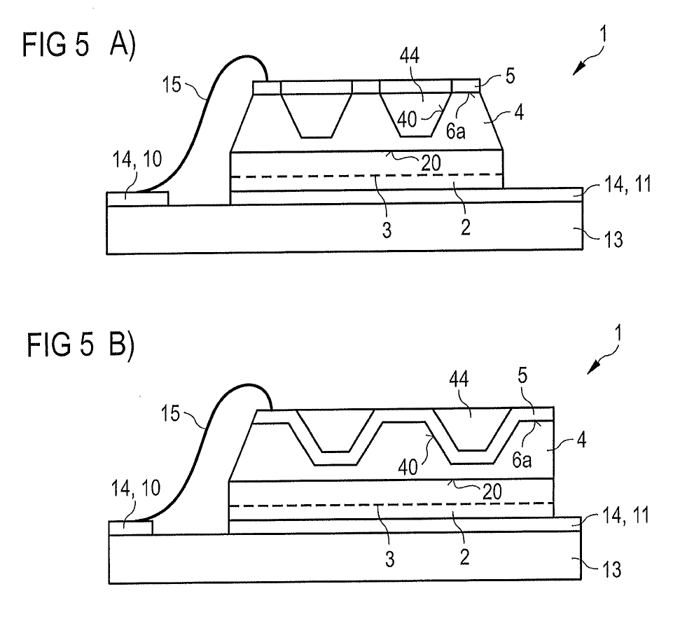

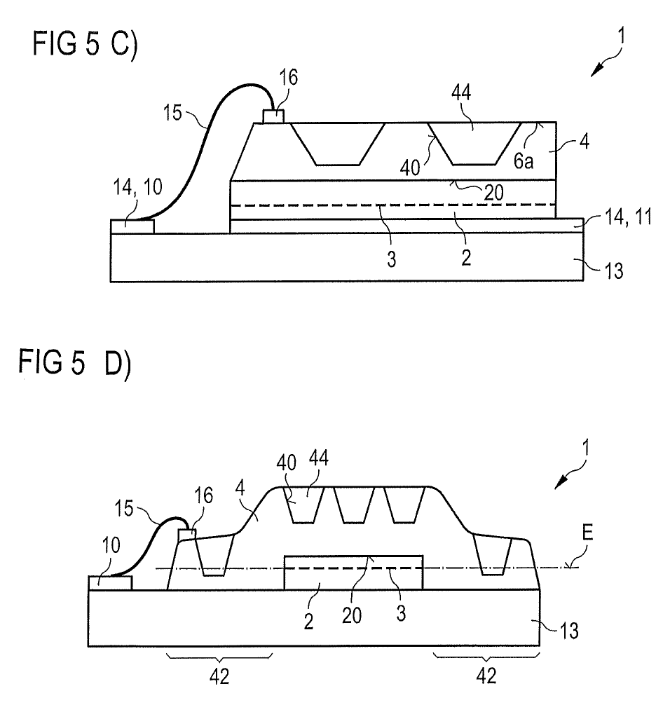

In accordance with the sectional view of the semiconductor chip 1 shown in FIG. 5A, an electrically conductive layer 5 is preferably applied directly on the outer boundary surface 6a of the light-outcoupling layer 4. The conductive layer 5 is completely penetrated by the recesses 44. The facets 40 of the recesses 44 are not covered by a material of the conductive layer 5. This type of layer 5 can be used to supply current to the semiconductor layer sequence 2 even in the case of a comparatively low electrical conductivity of the material of the light-outcoupling layer 4 since the light-outcoupling layer 4 is comparatively thin. The layer 5 is connected to the n-contact 10 e.g. by a bond wire 15. N-side contacting is effected via the connection layer 14. It is possible that within the scope of production of the semiconductor chip 1, the conductive layer 5 serves as a mask to create the recesses 44 in the light-outcoupling layer 4.

In accordance with FIG. 5B, the conductive layer 5 is applied in a form-fitting manner with respect to the light-outcoupling layer 4 and has an approximately constant thickness. The conductive layer 5 can cover the light-outcoupling layer 4 completely, contrary to what is shown in FIG. 5B, according to which outer lateral boundary surfaces of the light-outcoupling layer 4 are not covered by the conductive layer 5. As a consequence, it is also possible to supply current to the semiconductor chip 1 in an efficient manner through a comparatively high-resistance light-outcoupling layer 4.

The semiconductor chip 1 as shown in FIG. 5C is free of a conductive layer, contrary to FIGS. 5A and 5B. However, the light-outcoupling layer 4 itself has a comparatively high electrical conductivity which means that lateral current distribution can be effected via the light-outcoupling layer 4. For example, a material of the light-outcoupling layer 4 is then a doped titanium oxide. The bond wire 15 electrically connects the light-outcoupling layer 4 directly to the n-contact 10. Optionally, a metallic contact surface 16 for the bond wire 15, which is referred to as a bond pad, is provided locally on a side of the light-outcoupling layer 4 remote from the semiconductor layer sequence 2.

The example in accordance with FIG. 5D illustrates a modification of the semiconductor chip 1 in accordance with FIG. 4B. A partial region of the carrier 13 is not covered by the light-outcoupling layer 4. Located in this partial region is the n-contact 10 from which the bond wire 15 extends as far as to the optional contact surface 16 located on the light-outcoupling layer 4. Unlike the illustration in FIG. 5D, it is likewise possible that the bond wire 15 is not attached to the light-outcoupling layer 4 in the part 42 next to the active layer 3, but rather above the radiation permeable surface 20.

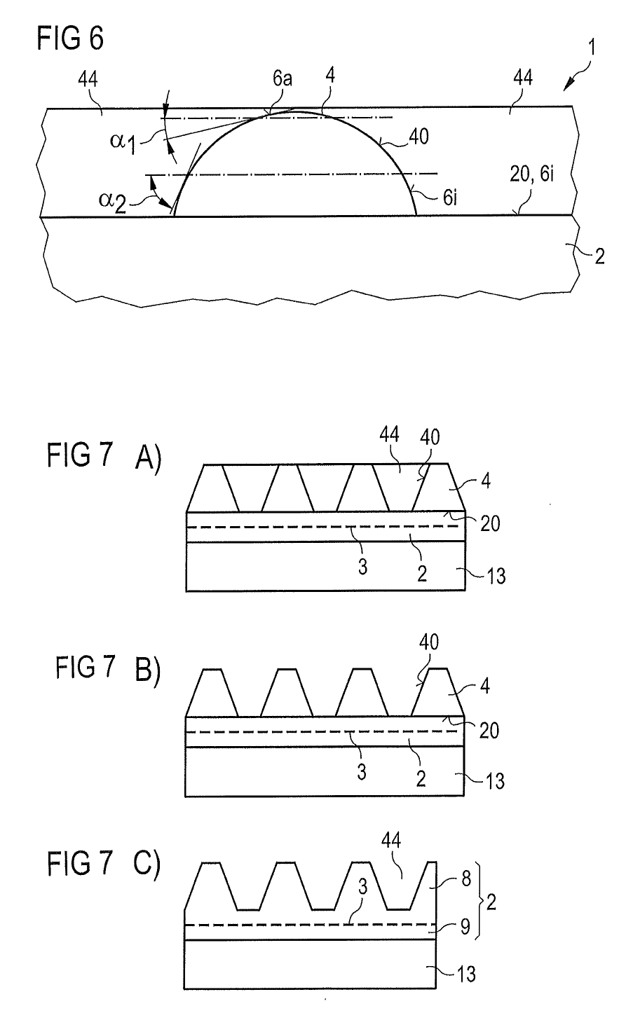

In the case of the example in accordance with FIG. 6, the recesses 44 comprise boundary surfaces which extend in a curved manner. In particular, the facets 40 which help to increase the light-outcoupling efficiency from the semiconductor layer sequence 2 are formed only by those parts of the boundary surfaces which have an angle a of 15° to 75°, preferably 30° to 60° in relation to the radiation permeable surface 20. The regions of the boundary surfaces of the recesses 44 outside the angular range are to be included in the inner or the outer boundary surfaces, cf. also FIGS. 1A and 1B.

FIG. 7A illustrates a sectional view of a further semiconductor chip. In accordance with FIG. 7A, the light-outcoupling layer 4 is also a contiguous, continuous layer, wherein the recesses 44 penetrate the light-outcoupling layer 4 completely towards the semiconductor layer sequence 2. In the case of this type of light-outcoupling layer 4, it is possible that when the recesses 44 are produced, material removal of the semiconductor layer 2 results on the radiation permeable surface 20. As a consequence, there is an increased risk that the semiconductor layer sequence 2, which in particular can be grown epitaxially to be very thin, is damaged or its mode of operation is impaired.

In accordance with FIG. 7B, the light-outcoupling layer 4 is formed by mutually separate, unconnected islands produced on the radiation permeable surface 20 of the semiconductor layer sequence 2. As a consequence, current is substantially prevented from being distributed via the light-outcoupling layer 4, even in the case of an electrically conductive light-outcoupling layer 4.

In the case of the semiconductor chip in accordance with FIG. 7C, the recesses 44 of the light-outcoupling structure are formed directly into a material of the semiconductor layer sequence 2. This requires a comparatively thick semiconductor layer sequence 2 associated with relatively high production costs.

The chips described herein are not limited by the description with reference to the examples. On the contrary, our chips comprise each new feature and each combination of features even if the feature or combination itself is not explicitly stated in the appended claims or examples.

1-14. (canceled)

15. An optoelectronic semiconductor chip comprising:
a semiconductor layer sequence having at least one active layer that generates electromagnetic radiation, and
a light-outcoupling layer applied at least indirectly on a radiation permeable surface of the semiconductor layer sequence,
wherein:
a material of the light-outcoupling layer is different from a material of the semiconductor layer sequence,
refractive indices of the materials of the light-outcoupling layer and the semiconductor layer sequence differ from each other by 20% at most,
recesses in the light-outcoupling layer form outcoupling structures with facets,
the light-outcoupling layer is not completely penetrated by the recesses in regions on the radiation permeable surface, and
the facets of the recesses have a total area which is at least 25% of an area of the radiation permeable surface.

16. The optoelectronic semiconductor chip as claimed in claim 15, wherein the light-outcoupling layer is electrically conductive and has an average surface resistance of 2.5Ω/□ to 50Ω/□.

17. The optoelectronic semiconductor chip as claimed in claim 15, wherein an electrically conductive layer is applied on a side of the light-outcoupling layer remote from the semiconductor layer sequence, and the conductive layer is penetrated completely by the recesses and does not cover the facets.

18. The optoelectronic semiconductor chip as claimed in claim 15, wherein the facets are those boundary surfaces or parts of the boundary surfaces of the recesses of the light-outcoupling layer which form an angle of 15° to 75° with the radiation permeable surface.

19. The optoelectronic semiconductor chip as claimed in claim 15, wherein a part of the light-outcoupling layer is provided in a lateral direction next to the semiconductor layer sequence, and all or some of the recesses in this part of the light-outcoupling layer intersect a plane defined by the active layer.

20. The optoelectronic semiconductor chip as claimed in claim 15, wherein the material of the light-outcoupling layer comprises or consists of at least one selected from the group consisting of a transparent conductive oxide, TiO₂, ZnS, AlN, SiC, BN and Ta₂O₅.

21. The optoelectronic semiconductor chip as claimed in claim 15, wherein a thickness of the light-outcoupling layer is 0.4 μm to 10 μm, and an average depth of the recesses is 0.3 μm to 9.5 μm.

22. The optoelectronic semiconductor chip as claimed in claim 15, wherein the recesses have an average diameter of 0.2 μm to 10 μm, and an average distance between two adjacent recesses is 0.3 μm to 10 μm.

23. The optoelectronic semiconductor chip as claimed in claim 15,
wherein the recesses comprise a pyramidal basic shape, a truncated pyramidal basic shape, a truncated conical basic shape or a conical basic shape,
the recesses are disposed in a regular grid, and
wherein an average grid constant of the grid is at least twice a main wavelength of the radiation produced in the active layer in a medium which surrounds the semiconductor chip at least indirectly.

24. The optoelectronic semiconductor chip as claimed in claim 15, wherein the recesses comprise inner boundary surfaces which adjoin the facets in a direction toward the semiconductor layer sequence, the inner boundary surfaces constitute in total an area of at least 10% of an area of the radiation permeable surface, the recesses and/or the light-outcoupling layer comprise outer boundary surfaces which adjoin the facets in a direction away from the semiconductor layer sequence, and the outer boundary surfaces constitute in total an area of at least 20% of the area of the radiation permeable surface.

25. The optoelectronic semiconductor chip as claimed in claim 15, wherein the material of the light-outcoupling layer has an optical refractive index of 2.25 to 2.60, and the semiconductor layer sequence is based upon GaN, InGaN, AlGaN and/or InGaAlN.

26. The optoelectronic semiconductor chip as claimed in claim 15, wherein the light-outcoupling layer is produced directly and in a form-fitting manner on the semiconductor layer sequence.

27. The optoelectronic semiconductor chip as claimed in claim 15, wherein the semiconductor layer sequence comprises several active layers, and at least two of the active layers emit, during operation, radiation with mutually different main wavelengths.

28. The optoelectronic semiconductor chip as claimed in claim 15, wherein:
the light-outcoupling layer is electrically conductive and has a thickness of 1 μm to 5 μm and is formed from a doped titanium oxide,
the recesses have an average diameter of 1 μm to 5 μm and the average distance between two adjacent recesses is 0.5 μm to 5 μm,
the recesses have a conical shape,
the angle between the radiation permeable surface and the facets of the recesses is 30° to 60°, and
the facets of the recesses have a total area which is at least 50% of the area of the radiation permeable surface.

29. The optoelectronic semiconductor chip as claimed in claim 15, wherein the conductive layer is formed in a form-fitting manner in relation to the recesses and has a smaller thickness than the light-outcoupling layer.

30. An optoelectronic semiconductor chip comprising:
a semiconductor layer sequence having at least one active layer that generates electromagnetic radiation, and
a light-outcoupling layer applied at least indirectly on a radiation permeable surface of the semiconductor layer sequence,
wherein:
a material of the light-outcoupling layer is different from a material of the semiconductor layer sequence,
refractive indices of the materials of the light-outcoupling layer and the semiconductor layer sequence differ from each other by 20% at most,
recesses in the light-outcoupling layer form outcoupling structures with facets,
the light-outcoupling layer is not completely penetrated by the recesses in regions on the radiation permeable surface,
the facets of the recesses have a total area which is at least 25% of an area of the radiation permeable surface,
an electrically conductive layer is applied on a side of the light-outcoupling layer remote from the semiconductor layer sequence, wherein the conductive layer is penetrated completely by the recesses and does not cover the facets, and
the light-outcoupling layer is electrically conductive and has an average surface resistance of 2.5Ω/□ to 50Ω/□.
